(19) United States
(12) Patent Application Publication
(10) Pub. No.: US 2021/0407447 A1
(43) Pub. Date: Dec. 30, 2021

(54) PIXEL CIRCUIT AND LIQUID CRYSTAL DISPLAY PANEL

(71) Applicant: TCL CHINA STAR OPTOELECTRONICS TECHNOLOGY CO., LTD, Shenzhen (CN)

(72) Inventors: Zhixiong Jiang, Shenzhen, Guangdong (CN); Yanhong Meng, Shenzhen, Guangdong (CN)

(21) Appl. No.: 16/617,185

(22) PCT Filed: Nov. 18, 2019
(86) PCT No.: PCT/CN2019/119049

§ 371 Date: Nov. 26, 2019

(30) Foreign Application Priority Data
Aug. 8, 2019 (CN) 201910730503.7

(51) Int. Cl. G09G 3/36; G02F 1/1368; G02F 1/1362

(52) U.S. Cl. CPC G09G 3/3648; G02F 1/1368; G02F 1/136286; G09G 2300/0465; G09G 2300/0809; G09G 2320/0242; G02F 1/13624

(57) ABSTRACT

The present disclosure discloses a pixel circuit and a liquid crystal display panel. The pixel circuit includes a main TFT and a sub-TFT connected in parallel. A resistance of the main TFT is less than a resistance of the sub-TFT. a voltage applied to the sub-TFT is less than a voltage applied to the main TFT by utilizing a voltage dividing function operated by the main TFT and the sub-TFT. The liquid crystal display panel includes the above-mentioned pixel circuit. The present disclosure can achieve different brightness of different domains by utilizing only two TFTs. Therefore, color shifting and transmittance of the panel is improved.

### FIELD OF INVENTION

The present disclosure relates to the field of display, particularly to the field of a pixel circuit and a liquid crystal display panel.

### BACKGROUND OF INVENTION

Liquid crystal displays (LCDs) have many advantages, such as a thin body, low power consumption, and no radiation, so have been widely used, such as LCD televisions, smart phones, digital cameras, tablets computers, computer screens, or notebooks screens, etc. LCDs have a dominate position in the display area.

The LCDs consist of a color filter (CF) substrate, a thin film transistor array substrate (TFT array substrate), and a liquid crystal layer disposed between the two substrates.

LCD panels include a plurality of pixels arranged in an array. When a driving voltage is applied to the two substrates, each pixel displays being driven by a pixel circuit.

In order to solve the phenomenon of color shifting at wide viewing angles, a skilled person in the art usually designs various pixel structures to achieve the purpose of reducing color shifting.

A common solution against color shift at large viewing angles uses spatial methods. The color shift happening at wide viewing angles is reduced by dividing ITO regions of a pixel unit into a plurality of domains and designing a plurality of TFTs to achieve different brightness in different domains

FIG. 1 illustrates a schematic structural diagram of a conventional pixel circuit which includes a main TFT 10, a sub-TFT 20, and a shared TFT 30.

FIG. 2 illustrates an equivalent circuit of the pixel circuit in FIG. 1.

When the scan line gate outputs a high level, a main liquid crystal capacitor (Clc-main) 40 and a storage capacitor Cst-A in an A region are charged and discharged through the main TFT 10. A sub liquid crystal capacitor (Clc-sub) 50 and a storage capacitor Cst-BA in a B region are charged and discharged through the sub-TFT 20. A voltage of a node of a sub pixel is pulled down through the shared TFT 30.

In order to achieve a voltage difference between a pixel voltage VpA and a pixel voltage VpB, it is usually necessary to adjust a proper ratio of a width of a width to a width of a channel of the shared TFT according to modulation for making a brightness difference between different domains achieves a predetermined level. Therefore, color shift is reduced at large viewing angles. However, to achieve different brightness between different domains, it is necessary to adopt at least three TFTs and three via holes. This design will reduce aperture ratios of the pixels. Therefore, the transmittances of LCD panels decrease and costs of backlight source increase.

Therefore, how to solve the above problems and implement low color shift display at large viewing angles without lowering the aperture ratios and the transmittances is one of the subjects of the industry.

### Technical Problems

The object of the present disclosure is provides a pixel circuit and a LCD panel to implement low color shift display at large viewing angles without lowering the aperture ratios and the transmittances.

### SUMMARY OF INVENTION

To achieve the above-mentioned object, the present disclosure adopts the following technical solutions.

An embodiment of the present disclosure provides a pixel circuit comprising a main thin film transistor (TFT) and a sub-TFT connected in parallel. A resistance of the main TFT is less than a resistance of the sub-TFT. A voltage applied to the sub-TFT is less than a voltage applied to the main TFT by utilizing a voltage dividing function operated by the main TFT and the sub-TFT.

Particularly, a gate of the main TFT is electrically connected to a scan line. A source of the main TFT is electrically connected to a data line. A drain of the main TFT is electrically connected to a first end of a main liquid crystal capacitor. A second end of the main liquid crystal capacitor is electrically connected to a common electrode on a color film. A gate of the sub-TFT is electrically connected to the scan line. A source of the sub-TFT is electrically connected to the data line. A drain of the main TFT is electrically connected to a first end of a sub liquid crystal capacitor. A second end of the sub liquid crystal capacitor is electrically connected to the common electrode on the color film. The voltage applied to the sub-TFT is less than the voltage applied to the main TFT by utilizing the voltage dividing function operated by the main TFT and the sub-TFT.

Particularly, a ratio of a length to a width of a channel of the sub-TFT is less than a ratio of a length to a width of a channel of the main TFT for making a charging efficiency of the sub-TFT less than a charging efficiency of the main TF

Particularly, the resistance of the main TFT is adjusted by adjusting a ratio of a length to a width of a channel of the main TFT.

Particularly, the resistance of the sub-TFT is adjusted by adjusting a ratio of a length to a width of a channel of the sub-TFT.

An embodiment of the present disclosure provides a liquid crystal display panel comprising a pixel circuit. The pixel circuit comprises a main thin film transistor (TFT) and a sub-TFT connected in parallel, a resistance of the main TFT is less than a resistance of the sub-TFT, and a voltage applied to the sub-TFT is less than a voltage applied to the main TFT.

Particularly, a gate of the main TFT is electrically connected to a scan line. A source of the main TFT is electrically connected to a data line. A drain of the main TFT is electrically connected to a first end of a main liquid crystal capacitor. A second end of the main liquid crystal capacitor is electrically connected to a common electrode on a color film. A gate of the sub-TFT is electrically connected to the scan line. A source of the sub-TFT is electrically connected to the data line. A drain of the main TFT is electrically connected to a first end of a sub liquid crystal capacitor. A second end of the sub liquid crystal capacitor is electrically connected to the common electrode on the color film. The voltage applied to the sub-TFT is less than the voltage applied to the main TFT by utilizing the voltage dividing function operated by the main TFT and the sub-TFT.

Particularly, a ratio of a length to a width of a channel of the sub-TFT is less than a ratio of a length to a width of a channel of the main TFT for making a charging efficiency of the sub-TFT less than a charging efficiency of the main TFT.

Particularly, the resistance of the main TFT is adjusted by adjusting a ratio of a length to a width of a channel of the main TFT.

Particularly, the resistance of the sub-TFT is adjusted by adjusting a ratio of length to a width of a channel of the sub-TFT.

### Beneficial Effects

The beneficial effect of the present disclosure is provides a pixel circuit and a LCD panel which improve color shift and aperture ratio. The different colors of different domains are achieved by adopting two TFTs so that color shift and transmittance of panel are improved.

### DESCRIPTION OF DRAWINGS

FIG. 1 illustrates a perspective structural diagram of a present pixel circuit.

FIG. 2 illustrates a circuit of the pixel circuit of FIG. 1.

FIG. 3 illustrates a perspective structural diagram of a pixel circuit of an embodiment of the present disclosure.

FIG. 4 illustrates a circuit of the pixel circuit of FIG. 3.

FIG. 5 illustrates an equivalent circuit of the pixel circuit of FIG. 4.

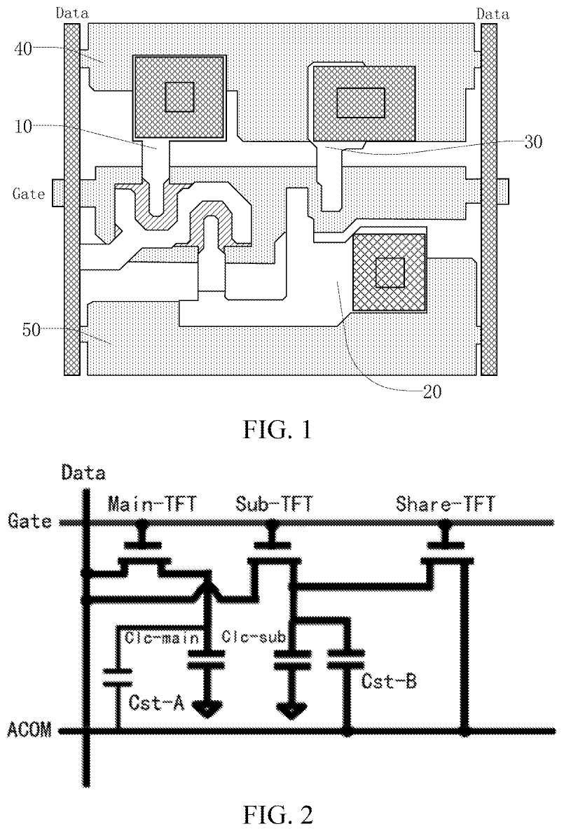

### DETAILED DESCRIPTION OF PREFERRED EMBODIMENTS

In order to clarify the objects, technical solutions, and advantages of embodiments of the present disclosure, the technical solutions of embodiments of the present disclosure will be clearly and completely described below accompanying with drawings. Obviously, the described embodiments are part of the embodiments of the present disclosure instead of all of embodiments. The components of the embodiments of the present disclosure, which are generally described and illustrated in the figures herein, may be arranged and designed in a various configurations.

The detailed description of the embodiments of the present disclosure, which is provided in the accompanying drawings, is not intended to limit the scope of the present disclosure. All of other embodiments obtained by a skilled person in the art based on the embodiments of the present disclosure without departing from the inventive scope fall within the scope of the disclosure.

Preferred embodiments of the present application will be described with accompanying with referenced drawings. The same reference numerals indicate the same elements throughout the specification. However, the present application is not limited by the embodiments, and variations and modifications may be adopted without departing from the technical aspect. In the following embodiments, the selection of the element name is based on the convenience of the description, which may be different from names used in practical.

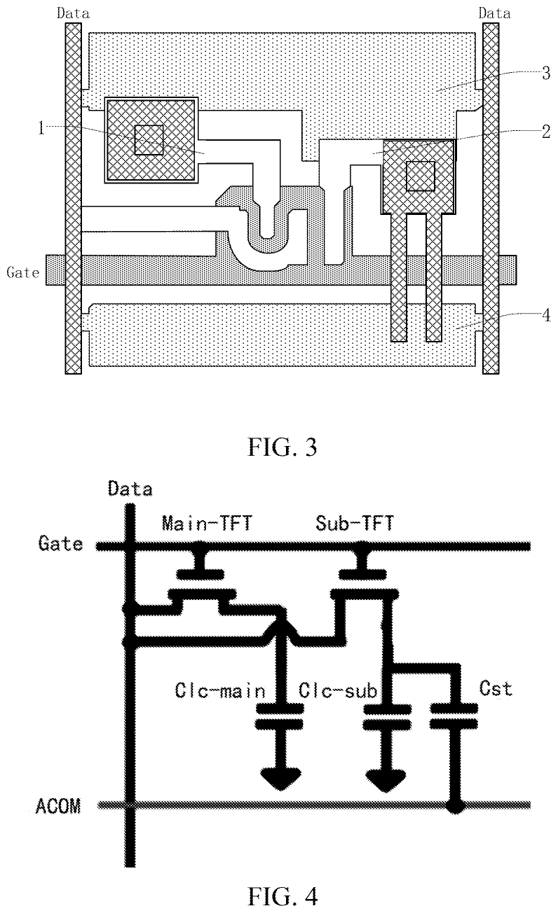

Please refer to FIG. 3 and FIG. 4. The main embodiment of the pixel circuit of the present disclosure adopts 2T, that is, adopts two thin film transistors (TFTs) which includes a main TFT 1 (main TFT in FIG. 4) and a sub-TFT 2 (sub-TFT in FIG. 4). A resistance of the main TFT 1 is less than a resistance of the sub-TFT 2. A voltage applied to the sub-TFT s is less than a voltage applied to the main TFT a by utilizing a voltage dividing function operated by the main TFT land the sub-TFT 2. Thus a voltage difference between the main TFT 1 and the sub-TFT 2 is achieved. Different brightness of different domains is achieved so that color shift is reduced at large viewing angles.

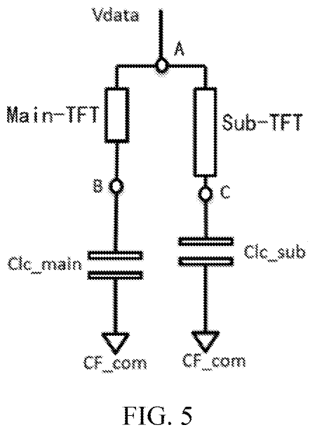

In this embodiment, a gate of the main TFT 1 is electrically connected to a scan line. A source of the main TFT 1 is electrically connected to a data line. A drain of the main TFT 1 is electrically connected to one end of a main liquid crystal capacitor 3 (Clc-main shown in FIG. 4 and FIG. 5). The other end of the main liquid crystal capacitor 3 is electrically connected to a common electrode on a color film CF-com. A gate of the sub-TFT 2 is electrically connected to the scan line (Gate). A source of the sub-TFT 2 is electrically connected to the data line (Data). A drain of the sub-TFT 2 is electrically connected to one end of a sub liquid crystal capacitor 4 (Clc-sub shown in FIG. 4 and FIG. 5). The other end of the sub liquid crystal capacitor 4 is electrically connected to the common electrode on the color film CF-coin. The voltage of the sub-TFT 2 is less than the voltage of the main TFT 1 by utilizing the voltage dividing function operated by the main TFT land the sub-TFT 2.

In the embodiment, a ratio of a length to a width of a channel of the sub-TFT 2 is less than the a ratio of a length to a width of a channel of the main TFT 1 for making a charging efficiency of the sub-TFT 2 less than a charging efficiency of the main TFT 1.

In this embodiment, the resistance of the main TFT 1 is adjusted by adjusting the ratio of the length to the width of the channel of the main TFT 1.

In this embodiment, the resistance of the sub-TFT 2 is adjusted by adjusting the ratio of the length to the width of the channel of the sub-TFT 2.

Specifically, the resistances of the main TFT 1 and the sub-TFT 2 are changed by adjusting the ratio of the length to the width of the channel (W/L value) of the main TFT 1 and the sub-TFT 1. The voltage difference between the main TFT 1 and the sub-TFT 2 is achieved by resistor division to obtain low color effect as the 3TFT structure achieved. An equivalent circuit is shown in FIG. 4. The main TFT 1 and the sub-TFT 2 are viewed as resistances. The resistance of the sub-TFT 2 is designed to be larger than the resistance of the main TFT 1 so that a voltage at point C is less than a voltage at point B. Therefore, low color shift at large viewing angles are achieved.

In order to achieve the same low color effect as the 3 TFT structure achieved, simulations of low color effect of the 2 TFT are implemented. Adjusting values W of the main TFT 1 and the sub-TFT 2 while values L of the main TFT 1 and the sub-TFT 2 are static. The simulation results show that when the W value of the sub-TFT 2 is half of the W value of the main TFT 1, the low color effect is equivalent to 3TFT structure.

The present disclosure further provides a liquid crystal display panel including a pixel circuit. The pixel circuit includes the main TFT 1 and the sub-TFT 2 connected in parallel. The resistance of the main TFT 1 is less than the resistance of the sub-TFT 2. The voltage applied to the sub-TFT 2 is less than the voltage applied to the main TFT 1 by utilizing the voltage dividing function operated by the main TFT land the sub-TFT 2. Different brightness of different domains are achieved by voltage differences between the main TFT land the sub-TFT 2, and the effect of low color shift at a large viewing angle is achieved.

In this embodiment, the gate of the main TFT 1 is electrically connected to the scan line, the source of the main TFT is electrically connected to the data line, and the drain of the main TFT is electrically connected to one end of the main liquid crystal capacitor 3. The other end of the main liquid crystal capacitor 3 is electrically connected to the common electrode on the color film CF-com. The gate of the sub-TFT 2 is electrically connected to the scan line, the source of the sub-TFT 2 is electrically connected to the data line, and the drain of the sub-TFT 2 is electrically connected to one end of the sub-liquid crystal capacitor 4. The other end of the crystal capacitor 4 is electrically connected to the common electrode on the color film CF-com. The voltage of the sub-TFT2 is less than the voltage of the main TFT1 by utilizing the voltage dividing function operated by the main TFT land the sub-TFT 2.

In the embodiment, the ratio of the length to the width of the channel of the sub-TFT 2 is less than the ratio of the length to the width of the channel of the main TFT 1 for making the charging efficiency of the sub-TFT 2 less than the charging efficiency of the main TFT 1.

In this embodiment, the resistance of the main TFT 1 is adjusted by adjusting the ratio of the length to the width of the channel of the main TFT 1.

In this embodiment, the resistance of the sub-TFT 2 is adjusted by adjusting the ratio of the length to the width of the channel of the sub-TFT 2.

Specifically, the resistances of the main TFT 1 and the sub-TFT 2 are changed by adjusting the ratio of the length to the width of the channel (W/L value) of the main TFT 1 and the sub-TFT 1. The voltage difference between the main TFT 1 and the sub-TFT 2 is achieved by resistor division to obtain low color effect as the 3TFT structure achieved. An equivalent circuit is shown in FIG. 5. The main TFT 1 and the sub-TFT 2 are viewed as resistances. The resistance of the sub-TFT 2 is designed to be larger than the resistance of the main TFT 1 so that a voltage UC at point C is less than a voltage UB at point B. Therefore, low color shift at large viewing angles are achieved.

In order to achieve the same low color effect as the 3 TFT structure achieved, simulations of low color effect of the 2 TFT are implemented. Adjusting values W of the main TFT 1 and the sub-TFT 2 while values L of the main TFT 1 and the sub-TFT 2 are static. The simulation results show that when the W value of the sub-TFT 2 is half of the W value of the main TFT 1, the low color effect is equivalent to 3TFT structure.

The present disclosure provides a pixel circuit and a liquid crystal display panel which can significantly improve the color shift and ensure the aperture ratios of pixels Different brightness of different domains are achieved by utilizing only two TFTs. Therefore, color shift and transmittance of panel EW improved.

The above description is only a preferred embodiment of the present application which only illustrates aspects of the applied technologies. It should be understood by a skilled person in the art, the scope of the present disclosure referred to in the present application is not limited to the specific combination of the above technical features. Variations, modifications, and any combination of equivalent features, such as substitutional features which are similar to the above mentioned features, without departing from the aspects of the present disclosure should fall in the protected scope of the present disclosure. The above description is only a preferred embodiment of the present disclosure, and it should be noted that a skilled person in the art can also make several improvements and refinements without departing from the aspects of the present disclosure. It should be considered as the protected scope of the present disclosure.

What is claimed is:

1. A pixel circuit, comprising:
a main thin film transistor (TFT) and a sub-TFT connected in parallel, wherein a resistance of the main TFT is less than a resistance of the sub-TFT, and a voltage applied to the sub-TFT is less than a voltage applied to the main TFT by utilizing a voltage dividing function operated by the main TFT and the sub-TFT.

2. The pixel circuit according to claim 1, wherein a gate of the main TFT is electrically connected to a scan line, a source of the main TFT is electrically connected to a data line, a drain of the main TFT is electrically connected to a first end of a main liquid crystal capacitor, and a second end of the main liquid crystal capacitor is electrically connected to a common electrode on a color film;
a gate of the sub-TFT is electrically connected to the scan line, a source of the sub-TFT is electrically connected to the data line, and a drain of the main TFT is electrically connected to a first end of a sub liquid crystal capacitor; a second end of the sub liquid crystal capacitor is electrically connected to the common electrode on the color film; and
the voltage applied to the sub-TFT is less than the voltage applied to the main TFT by utilizing the voltage dividing function operated by the main TFT and the sub-TFT.

3. The pixel circuit according to claim 1, wherein a ratio of a length to a width of a channel of the sub-TFT is less than a ratio of a length to a width of a channel of the main TFT for making a charging efficiency of the sub-TFT less than a charging efficiency of the main TFT.

4. The pixel circuit according to claim 1, wherein the resistance of the main TFT is adjusted by adjusting a ratio of a length to a width of a channel of the main TFT.

5. The pixel circuit according to claim 1, wherein the resistance of the sub-TFT is adjusted by adjusting a ratio of a length to a width of a channel of the sub-TFT.

6. A liquid crystal display panel comprising a pixel circuit, wherein the pixel circuit comprises a main thin film transistor (TFT) and a sub-TFT connected in parallel, a resistance of the main TFT is less than a resistance of the sub-TFT, and a voltage applied to the sub-TFT is less than a voltage applied to the main TFT by utilizing a voltage dividing function operated by the main TFT and the sub-TFT.

7. The liquid crystal display panel according to claim 6, wherein a gate of the main TFT is electrically connected to a scan line, a source of the main TFT is electrically connected to a data line, a drain of the main TFT is electrically connected to a first end of a main liquid crystal capacitor, a second end of the main liquid crystal capacitor is electrically connected to a common electrode on a color film;
a gate of the sub-TFT is electrically connected to the scan line, a source of the sub-TFT is electrically connected to the data line, a drain of the main TFT is electrically connected to a first end of a sub liquid crystal capacitor, and a second end of the sub liquid crystal capacitor is electrically connected to the common electrode on the color film;
the voltage applied to the sub-TFT is less than the voltage applied to the main TFT by utilizing the voltage dividing function operated by the main TFT and the sub-TFT.

8. The liquid crystal display panel according to claim 6, wherein a ratio of a length to a width of a channel of the sub-TFT is less than a ratio of a length to a width of a channel of the main TFT for making a charging efficiency of the sub-TFT less than a charging efficiency of the main TFT.

9. The liquid crystal display panel according to claim 6, wherein the resistance of the main TFT is adjusted by adjusting a ratio of a length to a width of a channel of the main TFT.

10. The liquid crystal display panel according to claim 6, wherein the resistance of the sub-TFT is adjusted by adjusting a ratio of length to a width of a channel of the sub-TFT.
